(19) United States
(12) Patent Application Publication
(10) Pub. No.: US 2009/0291393 A1
(43) Pub. Date: Nov. 26, 2009

(54) POSITIVE PHOTORESIST COMPOSITION AND METHOD OF FORMING PHOTORESIST PATTERN USING THE SAME

(75) Inventors: Koichi Misumi, Kawasaki-shi (JP); Koji Saito, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo Co., Ltd., Kawasaki-shi (JP)

(21) Appl. No.: 12/095,208

(22) PCT Filed: Dec. 5, 2006
(86) PCT No.: PCT/JP2006/324272

§ 371 Date: May 28, 2008

(30) Foreign Application Priority Data
Dec. 6, 2005 (JP) 2005-351377

(51) Int. Cl. G03F 7/004; G03F 7/20

(52) U.S. Cl. 430/286.1; 430/326

(57) ABSTRACT

A positive photoresist composition capable of forming a film thickness of 5 μm or greater, preventing cracking due to thermal shock even if exposed to a low temperature atmosphere, having high sensitivity, and easily releasable with general solvents; and a method of forming a photoresist pattern using the positive photoresist composition. The positive photoresist composition contains (A) an alkali soluble novolak resin, (B) at least one plasticizer selected from an alkali soluble acrylic resin and an alkali soluble vinyl resin, and (C) a quinonediazide group-containing compound. The method of forming a photoresist pattern uses the positive photoresist composition.

### TECHNICAL FIELD

The present invention relates to a positive photoresist composition and a method for forming a photoresist pattern using the same. More particularly, the present invention relates to a positive photoresist composition suitable for use in processes in which dry etching is performed under conditions at a low temperature in manufacture of MEMS elements such as microsensors and in manufacture of through electrodes, and a method for forming a photoresist pattern using the same.

### BACKGROUND ART

With recent progress of microtechnologies, so-called micromachine (MEMS: Micro Electro Mechanical System: ultramicro electric/mechanical complex) elements and small devices incorporating such an MEMS element have attracted attention. The MEMS element is formed as a minute structure on a substrate such as a silicon substrate or a glass substrate, and is electrically and further mechanically connected to a drive that brings out a mechanical driving force, and to a semiconductor integrated circuit that controls the drive. Using such an element, for example, microsensors and microactuators can be formed.

Also, aiming at further performance upgrading/high functionalization and downsizing/weight saving of semiconductor devices such as CPUs, memories and sensors, high-density packaging of a system with a three-dimensional lamination element in which silicon substrates or the like are laminated in a three-dimensional direction has been investigated. As one means to embody such high-density packaging, electrical connection to penetrate through the silicon substrate in its depthwise direction, i.e., formation of a through electrode was proposed. The high-density packaging with the through electrode is advantageous in first, enabling distortion by thermal contraction to be decreased by using as a substrate material of three-dimensional wiring such a silicon substrate since the material of the silicon substrate is the same as that of the functional element. In addition, such packaging is also advantageous in: superiority also in packaging of an element accompanied by intense heat generation (e.g., CPU, laser diode and the like), due to excellent thermal conductivity; and enabling the package size to be significantly reduced by taking out the terminal on the back face of the chip by means of the through electrode even in the case in which increase in the effective area of a detecting section as large as possible is intended such as in single silicon devices without lamination e.g., image sensors.

In any of the forming steps of an MEMS element and a through electrode as described above, formation by production and processing at a high aspect ratio (hole depth/aperture diameter) is required for the silicon substrate. Specifically, processing on the order of several μm to several thousands μm with respect to the silicon substrate is reportedly required. Currently, a lithography method using a photoresist has been utilized in formation by production and processing of such silicon substrates.

In the aforementioned lithography method, a common photoresist composition has been used conventionally, but because of low dry etching resistance of this common photoresist composition, formation by production of the silicon substrate with a high aspect ratio has been performed in such cases by repeating a series of steps of “coating of the photoresist-patterning-dry etching of the silicon substrate-removal of residues”. However, the operation of repeating such a series of steps results in inferior process yield, of course, and inevitably leads to high costs since a large amount of chemicals such as the photoresist must be used. In addition, there has been a problem of production of unevenness on the side wall of the pattern, or accumulation of residues on the bottom of the processed substrate.

Furthermore, a procedure for attaining a high etching rate of the silicon substrate has been examined by performing a dry etching process at a low temperature of no higher than 0° C.; however, the load on the photoresist pattern is so great in such a process at a low temperature that a problem of making release of the film difficult due to alteration of the temperature of the photoresist film, as well as a problem of cracking of the photoresist pattern, a problem of deterioration of dimensional accuracy, and the like have caused.

Required characteristics for the photoresist composition which enables formation by production of the silicon substrate under such a low temperature condition to be performed include: allowing for film formation having a film thickness of no less than 5 μm; precluding generation of a crack resulting from thermal shock even when exposed to a low temperature; being highly sensitive; capable of being easily released into a common solvent, and the like.

### DISCLOSURE OF THE INVENTION

### Problems to be Solved by the Invention

An object of the present invention is to provide a positive photoresist composition which solves the aforementioned prior art problems, i.e., which allows for film formation having a film thickness of no less than 5 μm, precludes generation of a crack resulting from thermal shock even when exposed to a low temperature, is highly sensitive and can be easily released into a common solvent, and a method for forming a photoresist pattern using the same.

### Means for Solving the Problems

In order to solve the aforementioned problems, aspects of the present invention are to provide a positive photoresist composition including (A) an alkali-soluble novolak resin, (B) at least one plasticizer selected from an alkali-soluble acrylic resin and an alkali-soluble vinyl resin, and (C) a quinone diazide group-containing compound, and a method for forming a photoresist pattern using this the positive photoresist composition.

### EFFECTS OF THE INVENTION

According to aspects of the present invention, a positive photoresist composition which allows for film formation having a film thickness of no less than 5 μm, precludes generation of a crack resulting from thermal shock even when exposed to a low temperature, is highly sensitive and can be easily released into a common solvent, and a method for forming a photoresist pattern using the same are provided.

### PREFERRED MODE FOR CARRYING OUT THE INVENTION

The present invention will be explained in more detail below.

### (A) Alkali-Soluble Novolak Resin:

The alkali-soluble novolak resin used as the component (A) in the present invention can be obtained by, for example, subjecting an aromatic compound having a phenolic hydroxyl group (hereinafter, merely referred to as “phenol”) and an aldehyde to addition condensation in the presence of an acid catalyst. Examples of the phenol which may be used in this process include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, p-phenylphenol, resorcinol, hydroquinone, hydroquinone monomethyl ether, pyrogallol, phloroglucinol, hydroxydiphenyl, bisphenol A, gallic acid, gallic acid ester, α-naphthol, β-naphthol, and the like. Also, examples of the aldehyde include formaldehyde, paraformaldehyde, furfural, benzaldehyde, nitrobenzaldehyde, acetaldehyde, and the like. Although the catalyst used in the addition condensation reaction is not limited in particular, for example, as the acid catalyst, hydrochloric acid, nitric acid, sulfuric acid, formic acid, oxalic acid, acetic acid or the like may be used.

The mass average molecular weight of such an alkali-soluble novolak resin is not particularly limited, but it is preferably 10,000-50,000.

(B) At Least One Plasticizer Selected from Alkali-Soluble Acrylic Resin and Alkali-Soluble Vinyl Resin:

It is preferable that the at least one plasticizer selected from an alkali-soluble acrylic resin and an alkali-soluble vinyl resin used as the component (B) in the present invention has a glass transition point (hereinafter, may be referred to as Tg) of no higher than 0° C. By using a plasticizer having such a glass transition point, resistance to the dry etching treatment can be ensured even though the dry etching treatment is carried out at an extremely low temperature of no higher than 0° C., and particularly from −20 to −100° C., and the crack is not generated even though cooling to a temperature from an ordinary temperature to an extremely low temperature is conducted.

Furthermore, in the present invention, the component (B) is preferably included in an amount of no less than 10 parts by mass per 100 parts by mass of the component (A). In particular, it is preferred that from 15 to 40 parts by mass of the component (B) per 100 parts by mass of the component (A) be included. Such a compounding ratio enables the crack resistance at a low temperature as described above to be ensured without deteriorating the characteristics of resolving performances.

As such a plasticizer, any general alkali-soluble acrylic resin and/or an alkali-soluble vinyl resin can be used as long as the aforementioned requirements are satisfied.

The alkali-soluble acrylic resin preferably has a mass average molecular weight of 100,000 to 800,000, and any of those having a glass transition point falling within the above range can be used.

Among such alkali-soluble acrylic resins, those having a constituent unit derived from at least one polymerizable compound selected from a (meth)acrylic acid alkyl ester and an etherified product thereof are particularly preferred in light of the low glass transition point, and those having 30% by mass or more such a constituent unit in the alkali-soluble acrylic resin are preferred. Such a constitution allows for attaining the crack resistance at a still lower temperature.

Illustrative examples of the at least one polymerizable compound selected from the (meth)acrylic acid alkyl ester and the etherified product thereof include radical polymerizable compounds such as methyl (meth)acrylate, ethyl (meth)acrylate, propyl (meth)acrylate, n-butyl (meth)acrylate, phenyl (meth)acrylate, benzyl (meth)acrylate, 2-methoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate and tetrahydrofurfuryl (meth)acrylate, and 2-methoxyethyl acrylate and methoxytriethylene glycol acrylate are preferred. These compounds may be used alone or in combination of two or more.

The constituent unit derived from the at least one polymerizable compound selected from the (meth)acrylic acid alkyl ester and the etherified product thereof is included in an amount of preferably 20 to 90% by mass, and more preferably 30 to 80% by mass in the alkali-soluble acrylic resin. The amount exceeding 90% by mass may lead to inferior miscibility with the alkali-soluble novolak resin solution (A), and thus Benard cell (pentagonal to heptagonal network pattern having nonuniformity produced on the surface of the coating film due to gravity or surface tension gradient) tends to be generated in prebaking, whereby a uniform resist film can be hardly obtained.

Furthermore, a constituent unit derived from a polymerizable compound including a (meth)acrylic acid derivative having a carboxyl group may be involved if desired. Illustrative examples of such a polymerizable compound include radical polymerizable compounds, e.g., monocarboxylic acids such as acrylic acid, methacrylic acid and crotonic acid; dicarboxylic acids such as maleic acid, fumaric acid and itaconic acid; methacrylic acid derivatives having a carboxyl group and an ester bond such as 2-methacryloyloxyethylsuccinic acid, 2-methacryloyloxyethylmaleic acid, 2-methacryloyloxyethylphthalic acid and 2-methacryloyloxyethylhexahydrophthalic acid, and the like, and acrylic acid and methacrylic acid are preferred. These compounds may be used alone or in combination of two or more.

The constituent unit derived from a polymerizable compound including a (meth)acrylic acid derive having a carboxyl group is included in an amount of preferably 2 to 50% by mass, and more preferably 5 to 40% by mass in the alkali-soluble acrylic resin. The amount of less than 2% by mass may lead to low solubility in alkali of the acrylic resin, whereby sufficient solubility in the developing solution is not achieved, and the removing property is deteriorated, whereby the resist may be left as a film on the substrate.

In the alkali-soluble acrylic resin, when two or more polymerizable compounds are used as a constitutional unit, the glass transition point may be determined by converting into a theoretical glass transition point. More specifically, the glass transition point of the constituent unit derived from each polymerizable compound is multiplied by the number of parts accounting for each constitutional unit, and thus resulting products are added followed by division by 100 to derive a theoretical glass transition point. This theoretical glass transition is preferably no higher than 0° C.

Such alkali-soluble acrylic resins have a mass average molecular weight of 100,000 to 800,000, and preferably 250,000 to 500,000. When the mass average molecular weight is less than 200,000, sufficient resistance of the resist film to the dry etching treatment at a low temperature cannot be achieved, while when the mass average molecular weight exceeds 800,000, the removing property may be deteriorated.

Additionally, the alkali-soluble acrylic resin may include other radical polymerizable compound as a monomer for the purpose of appropriately controlling physical and/or chemical properties. The “other radical polymerizable compound” herein means a radical polymerizable compound other than the polymerizable compound described above. Examples of such a radical polymerizable compound which can be used include (meth)acrylic acid hydroxyalkyl esters such as 2-hydroxyethyl (meth)acrylate and 2-hydroxypropyl (meth)acrylate; dicarboxylic acid diesters such as diethyl maleate and dibutyl fumarate; vinyl group-containing aromatic compounds such as styrene and α-methylstyrene; vinyl group-containing aliphatic compounds such as vinyl acetate; conjugated diolefins such as butadiene and isoprene; nitrile group-containing polymerizable compounds such as acrylonitrile and methacrylonitrile; chlorine atom-containing polymerizable compounds such as vinyl chloride and vinylidene chloride; amide bond-containing polymerizable compounds such as acrylamide and methacrylamide, and the like. These compounds may be used alone or in combination of two or more. The other radical polymerizable compound in the alkali-soluble acrylic resin (B) accounts for preferably less than 50% by weight, and more preferably less than 40% by weight.

Examples of polymerization solvent which may be used in synthesis of the alkali-soluble acrylic resin include alcohols such as ethanol and diethylene glycol; alkyl ethers of polyhydric alcohol such as ethylene glycol monomethyl ether, diethylene glycol monomethyl ether and diethylene glycol ethyl methyl ether; alkyl ether acetates of polyhydric alcohol such as ethylene glycol ethyl ether acetate and propylene glycol methyl ether acetate; aromatic hydrocarbons such as toluene and xylene; ketones such as acetone and methyl isobutyl ketone; esters such as ethyl acetate and butyl acetate, and the like. Among these, the alkyl ethers of polyhydric alcohol, and the alkyl ether acetates of polyhydric alcohol are particularly preferred.

As a polymerization catalyst for use in synthesis of the alkali-soluble acrylic resin, a common radical polymerization initiator can be used, and for example, azo compounds such as 2,2′-azobisisobutyronitrile; and organic peroxides such as benzoyl peroxide, di-tert-butyl peroxide can be used.

Meanwhile, in other aspect, an alkali-soluble vinyl resin can be also used as the plasticizer (B). The alkali-soluble vinyl resin referred to herein is a polymer obtained from a vinyl based compound. Examples of such polymer include polyvinyl chloride, polystyrene, polyhydroxystyrene, polyvinyl acetate, polyvinyl benzoate, polyvinyl methyl ether, polyvinyl ethyl ether, polyvinyl alcohol, polyvinylpyrrolidone, polyacrylic acid, polymethacrylic acid, polyacrylic acid esters, polyimide maleate, polyacrylamide, polyacrylonitrile, polyvinylphenol and copolymers thereof, and the like. Among these alkali-soluble vinyl resins, polyvinyl methyl ether is particularly preferred since it has a low glass transition temperature, whereby excellent crack resistance to low temperature conditions can be achieved.

The alkali-soluble vinyl resin has a mass average molecular weight of preferably 10,000 to 200,000, and more preferably 50,000 to 100,000.

The alkali-soluble acrylic resin and the alkali-soluble vinyl resin may be used as a mixture.

### (C) Quinone Diazide Group-Containing Compound:

Examples of the quinone diazide group-containing compound (C) include (I) polyhydroxybenzophenones such as 2,3,4-trihydroxybenzophenone, 2,4,4′-trihydroxybenzophenone, 2,4,6-trihydroxybenzophenone, 2,3,6-trihydroxybenzophenone, 2,3,4-trihydroxy-2′-methylbenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5-pentahydroxybenzophenone, 2,3′,4,4′,5′,6-hexahydroxybenzophenone and 2,3,3′,4,4′1,5-hexahydroxybenzophenone, (II) bis[(poly)hydroxyphenyl]alkanes such as bis(2,4-dihydroxyphenyl)methane, bis(2,3,4-trihydroxyphenyl)methane, 2-(4-hydroxyphenyl)-2-(4′-hydroxyphenyl)propane, 2-(2,4-dihydroxyphenyl)-2-(2′,4′-dihydroxyphenyl)propane, 2-(2,3,4-trihydroxyphenyl)-2-(2′,3′,4′-trihydroxyphenyl)propane, 4,4′-{1-[4-[2-(4-hydroxyphenyl)-2-propyl]phenyl]ethylidene}bisphenol, and 3,3′-dimethyl-{1-[4-[2-(3-methyl-4-hydroxyphenyl)-2-propyl]phenyl]ethylidene}bisphenol, (III) tris(hydroxyphenyl)methanes or methyl-substituted forms thereof such as tris(4-hydroxyphenyl)methane, bis(4-hydroxy-3,5-dimethylphenyl)-4-hydroxyphenylmethane, bis(4-hydroxy-2,5-dimethylphenyl)-4-hydroxyphenylmethane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-2,5-dimethylphenyl)-3,4-dihydroxyphenylmethane and bis(4-hydroxy-3,5-dimethylphenyl)-3,4-dihydroxyphenylmethane, (IV) bis(cyclohexylhydroxyphenyl) (hydroxyphenyl)methanes or methyl-substituted forms thereof such as bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(5-cyclohexyl-4-hydroxy-2-methylphenyl)-2-hydroxyphenylmethane, bis(5-cyclohexyl-4-hydroxy-2-methylphenyl)-3-hydroxyphenylmethane, bis(5-cyclohexyl-4-hydroxy-2-methylphenyl)-4-hydroxyphenylmethane, bis(3-cyclohexyl-2-hydroxyphenyl)-3-hydroxyphenylmethane, bis(5-cyclohexyl-4-hydroxy-3-methylphenyl)-4-hydroxyphenylmethane, bis(5-cyclohexyl-4-hydroxy-3-methylphenyl)-3-hydroxyphenylmethane, bis(5-cyclohexyl-4-hydroxy-3-methylphenyl)-2-hydroxyphenylmethane, bis(3-cyclohexyl-2-hydroxyphenyl)-4-hydroxyphenylmethane, bis(3-cyclohexyl-2-hydroxy phenyl)-2-hydroxyphenylmethane, bis(5-cyclohexyl-2-hydroxy-4-methylphenyl)-2-hydroxyphenylmethane and bis(5-cyclohexyl-2-hydroxy-4-methylphenyl)-4-hydroxyphenylmethane, (V) compounds having a hydroxyl group or an amino group such as phenol, p-methoxyphenol, dimethylphenol, hydroquinone, naphthol, pyrocatechol, pyrogallol, pyrogallol monomethyl ether, pyrogallol-1,3-dimethyl ether, gallic acid, aniline p-aminodiphenylamine and 4,4′-diaminobenzophenone, (VI) complete ester compounds, partial ester compounds, amidated products or partial amidated products of a homopolymer of a novolak, pyrogallol-acetone resin or p-hydroxystyrene, a copolymer thereof with a monomer which can copolymerize with the same, or the like, with quinone diazide group-containing sulfonic acid such as naphthoquinone-1,2-diazide-5-sulfonic acid or naphthoquinone-1,2-diazide-4-sulfonic acid or orthoanthraquinone diazide sulfonic acid, and the like.

Above all, the quinone diazide sulfonic acid ester represented by the following general formula (1) or (2) may be preferably used.

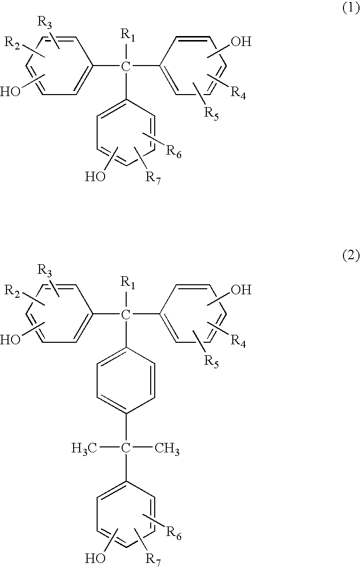

wherein R₁, R₂, R₃, R₄, R₅, R₆, and R₇ each independently represent a hydrogen atom, a substituted or unsubstituted alkyl group having 1 to 5 carbon atoms, a substituted or unsubstituted cycloalkyl group having 4 to 8 carbon atoms.

In particular, among the quinone diazide sulfonic acid esters that are the compounds represented by the general formula (1) or (2), the quinone diazide sulfonic acid ester that is the compound represented by the following chemical formula (3) may be more preferably used.

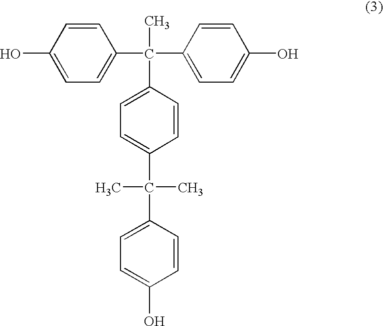

In the compounds represented by the above general formula (1), (2) or chemical formula (3), it is preferred that the naphthoquinone-1,2-diazide-sulfonyl group has a sulfonyl group bound at the 4- or 5-position. These compounds dissolve well in a solvent usually employed when the composition is used in a solution, and exhibits favorable miscibility with the alkali-soluble novolak resin (A) as a coating film-forming material. Thus, when they are used as a photosensitive component of the positive photoresist composition, a composition can be provided which leads to excellent image contrast and cross-sectional shape with high sensitivity, and which is also excellent in heat resistance and precludes generation of unwanted matters when used in a solution. The quinone diazide sulfonic acid ester that is the compound represented by the above general formula (1) or (2) may used alone, or as a mixture of two or more thereof.

The compound represented by the general formula (1) can be produced by, for example, condensation of 1-hydroxy-4-[1,1-bis(4-hydroxyphenyl)ethyl]benzene and naphthoquinone-1,2-diazide-sulfonyl chloride in a solvent such as dioxane, in the presence of alkali such as triethanolamine, carbonic acid alkali or hydrogen carbonate alkali, followed by complete esterification or partial esterification. Also, the compound represented by the general formula (2) can be produced by, for example, condensation of 1-[1-(4-hydroxyphenyl)isopropyl]-4-[1,1-bis(4-hydroxyphenyl)ethyl]benzene and naphthoquinone-1,2-diazide-sulfonyl chloride in a solvent such as dioxane, in the presence of alkali such as triethanolamine, carbonic acid alkali or hydrogen carbonate alkali, followed by complete esterification or partial esterification.

As the naphthoquinone-1,2-diazide-sulfonyl chloride, naphthoquinone-1,2-diazide-4-sulfonyl chloride or naphthoquinone-1,2-diazide-5-sulfonyl chloride is suitable.

In the composition of the present invention, the quinone diazide sulfonic acid ester that is a compound represented by the above general formula (1) or (2), and a quinone diazide group-containing compound other than such an ester can be used in combination as needed in the range not to compromise the effects of the present invention.

In the composition of the present invention, a common sensitizer, for example, 1-[1-(4-hydroxyphenyl)isopropyl]-4-[1,1-bis(4-hydroxyphenyl)ethyl]benzene mercaptoxazole, mercaptobenzoxazole, mercaptoxazoline, mercaptobenzothiazole, benzoxazolinone, benzothiazolone, mercaptobenzoimidazole, urazole, thiouracil, mercaptopyrimidine, imidazolone or a derivative thereof can be used in combination as needed in the range not to compromise the effects of the present invention.

In the composition of the present invention, one kind of the quinone diazide group-containing compound may be included alone as the component (C), or two or more thereof may be included. Also, it is desired that the component (C) be included in the range from 5 to 100 parts by mass, and preferably from 10 to 50 parts by mass per 100 parts by mass of the alkali-soluble novolak resin as the component (A). When the amount is less than 5 parts by mass, an image that strictly reproduces the pattern cannot be obtained, whereby the transferring properties may be deteriorated. Whereas, the amount exceeding 100 parts by mass is not preferred because the sensitivity of the photoresist may be significantly lowered.

The composition of the present invention is preferably used in the form of a solution prepared by dissolving (A) an alkali-soluble novolak resin, (B) at least one plasticizer selected from an alkali-soluble acrylic resin and an alkali-soluble vinyl resin, and (C) a quinone diazide group-containing compound in an appropriate solvent.

Examples of such a solvent include: ethylene glycol alkyl ethers such as ethylene glycol monomethyl ether, ethylene glycol monoethyl ether, ethylene glycol monopropyl ether and ethylene glycol monobutyl ether; diethylene glycol dialkyl ethers such as diethylene glycol dimethyl ether, diethylene glycol diethyl ether, diethylene glycol dipropyl ether and diethylene glycol dibutyl ether; ethylene glycol alkyl ether acetates such as methyl cellosolve acetate and ethyl cellosolve acetate; propylene glycol alkyl ether acetates such as propylene glycol monomethyl ether acetate, propylene glycol monoethyl ether acetate and propylene glycol monopropyl ether acetate; ketones such as acetone, methyl ethyl ketone, cyclohexanone and methyl amyl ketone; aromatic hydrocarbons such as toluene and xylene; cyclic ethers such as dioxane; and esters such as methyl 2-hydroxypropionate, ethyl 2-hydroxypropionate, ethyl 2-hydroxy-2-methyl propionate, ethyl ethoxyacetate, ethyl oxyacetate, methyl 2-hydroxy-3-methyl butanoate, 3-methoxybutyl acetate, 3-methyl-3-methoxybutyl acetate, ethyl formate, ethyl acetate, butyl acetate, methyl acetoacetate and ethyl acetoacetate. These solvents may be used alone or as a mixture of two or more.

The amount of the solvent as used preferably falls within the range such that no less than 30% by mass of the solid content is yielded for attaining a film thickness of no less than 5 μm by a spin coating process using the obtained positive photoresist composition.

A surface active agent may be also compounded as necessary for the purpose of improving coating characteristics, defoaming characteristics, leveling characteristics and the like in the composition of the present invention. Examples of the surface active agent which can be used include fluorinated surface active agents commercially available under the trade names of, e.g., BM-1000 and BM-1100 (manufactured by BM Chemie Co., Ltd.), Megaface F142D, F172, F173, and F183 (manufactured by Dainippon Ink and Chemicals, Ltd.), Fluorad FC-135, FC-170C, FC-430, and FC-431 (manufactured by Sumitomo 3M Limited), Surflon S-112, S-113, S-131, S-141, and S-145 (manufactured by Asahi Glass Co., Ltd.), SH-2SPA, SH-190, SH-193, SZ-6032, and SF-8428 (manufactured by Dow Corning Toray Silicone Co., Ltd.), and the like. The amount of the surface active agent as used is preferably no more than 5 parts by mass per 100 parts by mass of the alkali-soluble novolak resin (A).

An adhesion auxiliary agent can be also used in the composition of the present invention for improving adhesive properties with the substrate. A functional silane coupling agent is effective as the adhesion auxiliary agent which can be used. The functional silane coupling agent means a silane coupling agent having a reactive substituent such as a carboxyl group, a methacryloyl group, an isocyanate group or an epoxy group, and specific examples of the agent include trimethoxysilylbenzoic acid, γ-methacryloxypropyltrimethoxysilane, vinyltriacetoxysilane, vinyltrimethoxysilane, γ-glycidoxypropyltrimethoxysilane, β-(3,4-epoxycyclohexyl)ethyltrimethoxysilane, and the like. The amount of the compounded agent is preferably no more than 20 parts by mass per 100 parts by mass of the alkali-soluble novolak resin (A).

In addition, to the composition of the present invention may be also added for the purpose of fine adjustment of solubility in the alkali developing solution, monocarboxylic acid such as acetic acid, propionic acid, n-butyric acid, iso-butyric acid, n-valeric acid, iso-valeric acid, benzoic acid and cinnamic acid; hydroxymonocarboxylic acid such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid and syringic acid; polyvalent carboxylic acid such as oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, trimellitic acid, pyromellitic acid, cyclopentanetetracarboxylic acid, butanetetracarboxylic acid and 1,2,5,8-naphthalenetetracarboxylic acid; acid anhydride such as itaconic anhydride, succinic anhydride, citraconic anhydride, dodecenylsuccinic anhydride, tricarbanilic anhydride, maleic anhydride, hexahydrophthalic anhydride, methyltetrahydrophthalic anhydride, Himic anhydride, 1,2,3,4-butanetetracarboxylic acid, cyclopentanetetracarboxylic dianhydride, phthalic anhydride, pyromellitic anhydride, trimellitic anhydride, benzophenonetetracarboxylic anhydride, ethylene glycol bis anhydrous trimellitate and glycerin tris anhydrous trimellitate. Furthermore, a solvent having a high boiling point such as N-methylformamide, N,N-dimethylformamide, N-methylformanilide, N-methylacetamide, N,N-dimethlyacetamide, N-methylpyrrolidone, dimethyl sulfoxide, benzyl ethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenyl cellosolve acetate can be also added. The amount of the compound as used for the fine adjustment of solubility in the alkali developing solution can be regulated to meet the application and coating method, and is not particularly limited as long as it can be homogeneously mixed with the composition. Specifically, the amount may account for no more than 60% by mass, and preferably no more than 40% by mass of the resulting composition.

Moreover, a filler, a colorant, a viscosity modifier and the like can be also added to the composition of the present invention if necessary. Examples of the filler include silica, alumina, talc, bentonite, zirconium silicate, ground glass, and the like. Examples of the colorant include extender pigments such as alumina hydrate, clay, barium carbonate and barium sulfate; inorganic pigments such as zinc oxide, flake white, chrome yellow, red oxide, ultramarine blue, iron blue, titanium oxide, zinc chromate, red ocher and carbon black; organic pigments such as brilliant carmine 6B, permanent red 6B, permanent red R, benzidine yellow, copper phthalocyanine blue and copper phthalocyanine green; basic dyes such as magenta and rhodamine; direct dyes such as direct scarlet and direct orange; acidic dyes such as rhoserine and metanil yellow. Also, bentonite, silica gel, aluminum powder and the like can be exemplified as the viscosity modifier. These additives may be included in the range not to deteriorate the essential characteristics of the composition, preferably no more than 50% by mass of the resulting composition.

For the preparation of the composition according to the present invention, the components may be merely mixed and stirred by way of a general method when neither the filler nor the pigment is added, while when the filler and/or the pigment are added, dispersion and mixing may be allowed using a dispersion device such as a dissolver, homogenizer, or three-roll mill. In addition, the mixture may be further filtered by using a mesh, a membrane filter, or the like as needed.

When a photoresist film is formed with the composition of the present invention, the film thickness may be from five to several hundred μm. Although the upper limit of the film thickness depends on the intended shape of the silicon wafer processed, the film having a film thickness of approximately 1,000 μm can be formed, and it can be likewise applied to treatments under low temperature conditions.

The method for forming a photoresist pattern using the positive photoresist composition of the present invention can be performed, for example, as follows.

### (1) Formation of Coating Film:

A desired coating film is formed by coating the solution of the positive photoresist composition prepared as described above on a silicon wafer to give the thickness of 5 μm to 1,000 μm, and heating to remove the solvent. The coating method on the processed substrate which can be adopted includes any method such as a spin-coating method, a roll-coating method, a screen printing method, or an applicator method. The prebaking conditions of the coating film of the photoresist composition of the present invention may vary depending on the type of each component in the composition, the compounding ratio, the film thickness of the coating, and the like. Usually the conditions may involve a temperature of 70 to 130° C. and preferably 80 to 120° C. for a time period of 2 to 60 min.

### (2) Radiation Exposure:

Thus obtained coating film is exposed by irradiating a radiation ray such as e.g., an ultraviolet ray or a visible light ray having a wavelength of 300 to 500 nm through a mask having a predetermined pattern. As the light source of these radiation rays, a low-pressure mercury lamp, a high-pressure mercury lamp, an ultra high-pressure mercury lamp, a metal halide lamp, an argon gas laser lamp, or the like can be used. The radiation ray herein means ultraviolet ray, visible light ray, far-ultraviolet ray, X-ray, electron beam and the like. The irradiation dose of the radiation ray may vary depending on the kind of each component in the composition, the compounding amount, the film thickness of the coating film and the like, and for example, when an ultra high-pressure mercury lamp is used, the dose may be 100 to 2000 mJ/cm².

### (3) Development:

In the developing process following the irradiation of the radiation ray, an aqueous alkaline solution is used as a developing solution to dissolve and remove unwanted regions, whereby only the regions unirradiated by the radiation ray are left. As the developing solution, an aqueous solution of an alkali such as, for example, sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, dimethylethanolamine, triethanolamine, tetramethylammonium hydroxide, tetraethylammonium hydroxide, pyrrole, piperidine, 1,8-diazabicyclo[5,4,0]-7-undecene or 1,5-diazabicyclo[4,3,0]-5-nonane can be used. Also, an aqueous solution prepared by adding an adequate amount of a water-soluble organic solvent such as methanol or ethanol, or a surface active agent to the aqueous solution of the alkali can be used as the developing solution. The developing time may vary depending on the kind of each component of the composition, the compounding ratio and the dried film thickness of the composition, and is usually for 1 to 30 min. The method of the development may be any one of a liquid-filling method, a dipping method, a paddle method, a spray developing method, and the like. After the development, washing with running water for 30 to 90 seconds is followed by air drying with an air gun, drying in an oven, or the like.

### EXAMPLES

Hereinafter, the present invention will be explained more specifically by way of Examples and Comparative Examples; however the present invention is not limited to thereto. Also, unless other wise stated in particular, the “part” represents part by mass, and “%” represents % by mass.

### (A) Synthesis of Alkali-Soluble Novolak Resin

### Synthesis Example 1

Meta-cresol and para-cresol were mixed at a weight ratio of 60:40, and formalin was added to the mixture. A cresol novolak resin was obtained by condensation using an oxalic acid catalyst according to a common procedure. This resin was subjected to a fractionating treatment, whereby a low-molecular fraction was eliminated to obtain a novolak resin having a weight average molecular weight of 15,000. This resin is referred to as novolak resin (A).

### (B) Synthesis of Alkali-Soluble Acrylic Resin

### Synthesis Example 2

After substituting a flask equipped with a stirrer, a refluxer, a thermometer and a driptank with nitrogen, 200 g of propylene glycol methyl ether acetate was charged as a solvent, and then stirring was started. Thereafter, the temperature of the solvent was elevated to 80° C. The driptank was charged with 0.5 g of 2,2′-azobisisobutyronitrile as a polymerization catalyst, 130 g of 2-methoxyethyl acrylate, 50.0 g of benzyl methacrylate and 20.0 g of acrylic acid, and the mixture was stirred until the polymerization catalyst was dissolved.

Thereafter, this solution was added dropwise into the flask uniformly over 3 hrs, and subsequently polymerization was performed at 80° C. for 5 hrs. Thereafter, the mixture was cooled to room temperature to obtain an acrylic resin (B1).

### Preparation Example 1

After dissolving 70 parts of the novolak resin (A), 15 parts of the acrylic resin (B1), and 15 parts of a photosensitive agent (C) prepared by allowing 1 mol of a compound represented by the chemical formula (3) to react with 2 mol of 1,2-naphthoquinonediazide-4-sulfonyl chloride in 150 parts of propylene glycol methyl ether acetate as a solvent, the solution was filtrated through a membrane filter having a pore size of 1.0 μm, whereby a positive photoresist composition (PR1) was prepared.

### Preparation Example 2

A positive photoresist composition (PR2) was prepared by a similar operation to Preparation Example 1 except that 70 parts of the novolak resin (A), 20 parts of the acrylic resin (B1), and 10 parts of the photosensitive agent (C) prepared by allowing 1 mol of the compound represented by the chemical formula (3) to react with 2 mol of 1,2-naphthoquinonediazide-4-sulfonyl chloride were used.

### Preparation Example 3

A positive photoresist composition (PR3) was prepared by a similar operation to Preparation Example 1 except that 60 parts of the novolak resin (A), 20 parts of the acrylic resin (B1), and 20 parts of the photosensitive agent (C) prepared by allowing 1 mol of the compound represented by the chemical formula (3) to react with 2 mol of 1,2-naphthoquinonediazide-4-sulfonyl chloride were used.

### Preparation Example 4

A positive photoresist composition (PR4) was prepared by a similar operation to Preparation Example 1 except that an alkali-soluble vinyl methyl ether polymer obtained by subjecting methyl vinyl ether to a polymerization reaction in a gas phase under high temperature and high pressure in the presence of a catalyst was used in place of the acrylic resin (B1).

### Comparative Preparation Example 1

A positive photoresist composition (PR5) was prepared by a similar operation to Preparation Example 1 except that the acrylic resin (B1) was not used.

### Example 1

After coating the positive photoresist composition (PR1) on a silicon substrate at 1,000 rpm for 25 sec, prebaking on a hot plate was conducted at 110° C. for 6 min to form a coating film having a film thickness of about 20 μm. Next, exposure with an ultraviolet ray was carried out at light exposure of 1500 mJ/cm² using an ultra high-pressure mercury lamp (USH-250D, manufactured by Ushio Inc.) through a pattern mask for the measurement of resolution. It was developed in a developing solution (trade name: PMER series, P-7G, manufactured by Tokyo Ohka Kogyo Co., Ltd.). Thereafter, washing with running water and nitrogen blowing were performed to obtain a cured product with a hole pattern having a diameter of 50 μm.

Using a reactive gas constituted with CF₄, SF₆, O₂ and N₂ in the state in which the silicon substrate was cooled to −20° C., the silicon substrate was subjected to an etching treatment to the depth of 180 μm with the patterned cured product as a mask. In this process, formation by production of a hole having a diameter of 180 μm could be perfected on the silicon substrate without generating a crack or the like on the resist pattern.

### Example 2

The etching treatment was carried out with a similar procedure to Example 1 except that the positive photoresist composition was changed to (PR2). Thus, it was ascertained that any crack was not similarly generated on the resist pattern.

### Example 3

The etching treatment was carried out with a similar procedure to Example 1 except that the positive photoresist composition was changed to (PR3). Thus, it was ascertained that any crack was not similarly generated on the resist pattern.

### Example 4

The etching treatment was carried out with a similar procedure to Example 1 except that the positive photoresist composition was changed to (PR4). Thus, it was ascertained that any crack was not similarly generated on the resist pattern.

### Comparative Example 1

Generation of the crack on the resist pattern was revealed immediately after cooling the silicon substrate to −20° C., whereby it was verified that the etching treatment could not be carried out.

1. A positive photoresist composition comprising (A) an alkali-soluble novolak resin, (B) at least one plasticizer selected from an alkali-soluble acrylic resin and an alkali-soluble vinyl resin, and (C) a quinine diazide group-containing compound.

2. The positive photoresist composition according to claim 1 wherein the positive photoresist composition is subjected to a dry etching process carried out at no higher than 0° C.

3. The positive photoresist composition according to claim 1 wherein the positive photoresist composition is subjected to a process for forming a photoresist film having a film thickness of 5 to 200 μm.

4. The positive photoresist composition according to claim 1 wherein the component (B) is included in an amount of no less than 10 parts by mass per 100 parts by mass of the component (A).

5. The positive photoresist composition according to claim 1 wherein the component (B) is an alkali-soluble acrylic resin, and has a mass average molecular weight of 100,000 to 800,000.

6. The positive photoresist composition according to claim 1 wherein the component (B) is an alkali-soluble acrylic resin, and has a glass transition point (Tg) of no higher than 0° C.

7. The positive photoresist composition according to claim 1 wherein the component (B) is an alkali-soluble acrylic resin, and has a constituent unit derived from at least one polymerizable compound selected from a (meth)acrylic acid alkyl ester and an etherified product thereof.

8. The positive photoresist composition according to claim 1 wherein the component (B) is an alkali-soluble acrylic resin, and has a constituent unit derived from at least one polymerizable compound selected from the group consisting of a (meth)acrylic acid alkyl ester and an etherified product thereof in an amount of no less than 30% by mass in the alkali-soluble acrylic resin.

9. The positive photoresist composition according to claim 1 wherein the component (B) is an alkali-soluble vinyl resin, and has a mass average molecular weight of 10,000 to 200,000.

10. The positive photoresist composition according to claim 1 wherein the component (B) is an alkali-soluble vinyl resin, and is polyvinyl alkyl ether.

11. The positive photoresist composition according to claim 1 wherein the component (C) is included in an amount from 5 to 100 parts by weight per 100 parts by weight of the component (A).

12. A method for forming a photoresist pattern comprising: coating the positive photoresist composition according to claim 1 on a substrate of an electronic part to form a photoresist film having a thickness from 5 to 200 μm; irradiating the resulting photoresist film with radiation through a mask having a predetermined pattern; and subjecting said irradiated film to a developing treatment.
